(19) United States
(12) Patent Application Publication
(10) Pub. No.: US 2022/0173349 A1
(43) Pub. Date: Jun. 2, 2022

(54) SWITCHING DEVICE STRUCTURE AND METHOD FOR PREPARING SAME, THIN FILM TRANSISTOR FILM LAYER AND DISPLAY PANEL

(71) Applicant: BOE Technology Group Co., Ltd., Beijing (CN)

(72) Inventor: Meng ZHAO, Beijing (CN)

(21) Appl. No.: 17/381,121

(22) Filed: Jul. 20, 2021

(30) Foreign Application Priority Data
Dec. 1, 2020 (CN) 202011388074.9

(51) Int. Cl. H01L 51/52; H01L 51/00

(52) U.S. Cl. CPC H01L 51/5206; H01L 51/0021; H01L 51/5221

(57) ABSTRACT

A switching device structure includes: a first gate structure disposed on a side of a substrate layer; a first buffer layer disposed on a side of the first gate structure and a side of the substrate layer; a first source-drain structure and an oxide semiconductor structure disposed on a side of the first buffer layer away from the substrate layer, the oxide semiconductor structure being in contact with a part of the first source-drain structure; a first insulating layer disposed on a side of the first source-drain structure and a side of the oxide semiconductor structure which are away from the first buffer layer; and a second gate structure and a second source-drain structure disposed on a side of the first insulating layer away from the first buffer layer, the second source-drain structure being electrically connected to the other part of the first source-drain structure.

### CROSS-REFERENCE TO RELATED APPLICATION

This application claims priority to Chinese Patent Application No. 202011388074.9, filed on Dec. 1, 2020 and entitled “SWITCHING DEVICE STRUCTURE AND METHOD FOR PREPARING SAME, THIN FILM TRANSISTOR FILM LAYER AND DISPLAY PANEL”, the disclosure of which is incorporated herein by reference in its entirety.

### TECHNICAL FIELD

The present disclosure relates to the field of display technologies, in particular to a switching device structure and a method for preparing the same, a thin film transistor film layer and a display panel.

### BACKGROUND

An organic electro luminescent display (OLED) has been gradually developed as a mainstream of the display field due to its excellent performances such as low power consumption, high color saturation, wide viewing angle, thin thickness and flexibility.

With the wide application of OLED products, the OLED products are facing a further demand pressure for reducing the power consumption or improving the stability.

Therefore, it is urgent to provide new technological improvements to alleviate the above-mentioned demand pressure.

### SUMMARY

The present disclosure provides a switching device structure and a method for preparing the same, a thin film transistor film layer and a display panel.

In a first aspect, the present disclosure provides a switching device structure. The switching device structure includes: a first gate structure, disposed on a side of a substrate layer:

a first buffer layer, disposed on a side of the first gate structure and the side of the substrate layer, the first gate structure being disposed between the substrate layer and the first buffer layer; a first source-drain structure, disposed on a side of the first buffer layer away from the substrate layer; an oxide semiconductor structure, disposed on the side of the first buffer layer away from the substrate layer, the oxide semiconductor structure being in contact with a part of the first source-drain structure; a first insulating layer, disposed on a side of the first source-drain structure and a side of the oxide semiconductor structure which are away from the first buffer layer, a second gate structure, disposed on a side of the first insulating layer away from the first buffer layer; and a second source-drain structure, disposed on the side of the first insulating layer away from the first buffer layer, the second source-drain structure being electrically connected to an other part of the first source-drain structure.

In a second aspect, the present disclosure provides a thin film transistor film layer. The thin film transistor film layer includes a polysilicon device structure and the switching device structure provided in the first aspect.

The polysilicon device structure comprises a polysilicon structure, a third insulating layer, a third gate structure, a fourth insulating layer, and a third source-drain structure that are sequentially laminated on a side of the substrate layer; a first gate structure, a first source-drain structure, an oxide semiconductor structure, and some of second source-drain structures in the switching device structure are disposed in a first region of the thin film transistor film layer; the polysilicon structure, the third gate structure, the third source-drain structure, and others of the second source-drain structures are disposed in a second region of the thin film transistor film layer; the third source-drain structure is electrically connected to the polysilicon structure; and each of the others of the second source-drain structures is electrically connected to a third source-drain structure.

In a third aspect, the present disclosure provides a display panel. The display panel includes the thin film transistor film layer provided in the second aspect, an anode layer, a light-emitting layer and a cathode layer which are sequentially laminated.

At least some of the others of the second source-drain structures of the thin film transistor film layer are electrically connected to the anode layer.

In a fourth aspect, the present disclosure provides a display apparatus. The display apparatus includes the switching device structure provided in the first aspect; or includes the thin film transistor film layer provided in the second aspect; or includes the display panel provided in the third aspect.

In a fifth aspect, the present disclosure provides a method for preparing a switching device structure. The method includes: preparing a first gate structure, a first buffer layer and a first source-drain structure which are sequentially laminated on a side of a substrate layer; preparing an oxide semiconductor structure on the first buffer layer, wherein the oxide semiconductor structure is in contact with a part of the first source-drain structure; depositing a first insulating layer on the first buffer layer, the first source-drain structure and the oxide semiconductor structure; and preparing a second gate structure and a second source-drain structure on the first insulating layer, wherein the second source-drain structure is electrically connected to an other part of the first source-drain structure.

In a sixth aspect, the present disclosure provides a method for preparing a thin film transistor film layer. The method includes: preparing a substrate layer, wherein the thin film transistor film layer comprises a first region and a second region; and a polysilicon device structure in the thin film transistor film layer is disposed in the second region; preparing a first gate structure on a side, away from the substrate layer, of a first portion of the substrate layer which is disposed in the first region; preparing a first buffer layer on the substrate layer and on a side of the first gate structure away from the substrate layer; preparing a first source-drain structure on a side, away from the substrate layer, of a part of the first buffer layer which is disposed in the first region; preparing an oxide semiconductor structure on a side, away from the first gate structure, of the part of the first buffer layer which is disposed in the first region, and enabling the oxide semiconductor structure to be connected to a part of the first source-drain structure; preparing a first insulating layer on a side of the oxide semiconductor structure and a side of the first source-drain structure which are away from the first buffer layer; preparing a second gate structure on a side, away from the first gate structure, of a part of the first insulating layer which is disposed in the first region; and preparing a second source-drain structure on a side of the first insulating layer away from the first buffer layer, and enabling a part of the second source-drain structure to be electrically connected to an other part of the first source-drain structure.

### BRIEF DESCRIPTION OF THE DRAWINGS

FIG. 1 is a schematic structural diagram of a switching device structure in an implementation according to an embodiment of the present disclosure;

FIG. 2 is a schematic structural diagram of a switching device structure in another implementation according to an embodiment of the present disclosure;

FIG. 3 is a schematic diagram of a positional relationship of a first source-drain structure, a second source-drain structure and an oxide semiconductor structure in FIG. 2;

FIG. 4 is a schematic structural diagram of a switching device structure in still another implementation according to an embodiment of the present disclosure;

FIG. 5 is a schematic diagram of a positional relationship of a first source-drain structure, a second source-drain structure and an oxide semiconductor structure in FIG. 4;

FIG. 6 is a schematic structural diagram of a thin film transistor film layer according to an embodiment of the present disclosure;

FIG. 7 is a schematic flowchart of a method for preparing a switching device structure according to an embodiment of the present disclosure;

FIG. 8 is a schematic flowchart showing the preparation of an oxide semiconductor structure on a first buffer layer in a method for preparing a switching device structure according to an embodiment of the present disclosure;

FIG. 9 is a schematic flowchart showing the preparation of a second gate structure and a second source-drain structure on a first insulating layer in a method for preparing the switching device structure according to an embodiment of the present disclosure;

FIG. 10 is a schematic flowchart of an extended method of a method for preparing a switching device structure according to an embodiment of the present disclosure;

FIG. 11 is a schematic structural diagram showing film layers after a first gate structure, a first buffer layer and a first source-drain structure which are sequentially laminated are prepared on a side of a substrate layer in an extended method of the method for preparing the switching device structure according to an embodiment of the present disclosure;

FIG. 12 is a schematic structural diagram showing film layers after a sacrificial layer is coated on the first buffer layer and the first source-drain structure in an extended method of the method for preparing the switching device structure according to an embodiment of the present disclosure;

FIG. 13 is a schematic structural diagram showing film layers after a photoresist structure is prepared on the sacrificial layer in an extended method of the method for preparing the switching device structure according to an embodiment of the present disclosure;

FIG. 14 is a schematic structural diagram showing film layers after a part of a sacrificial layer is stripped off by taking the photoresist structure as a mask, to expose a part of the first source-drain structure and a part of the first buffer layer in an extended method of the method for preparing the switching device structure according to an embodiment of the present disclosure;

FIG. 15 is a schematic structural diagram showing film layers after an oxide semiconductor layer is deposited on the photoresist structure, the exposed part of the first source-drain structure and the exposed part of the first buffer layer in an extended method of the method for preparing the switching device structure according to an embodiment of the present disclosure;

FIG. 16 is a schematic structural diagram showing film layers after the remaining sacrificial layer is stripped off to obtain the oxide semiconductor structure that is in contact with the part of the first source-drain structure in an extended method of the method for preparing the switching device structure according to an embodiment of the present disclosure;

FIG. 17 is a schematic structural diagram showing film layers after a first insulating layer is deposited on the first buffer layer, the first source-drain structure and the oxide semiconductor structure and a second gate structure is prepared on the first insulating layer in an extended method of the method for preparing the switching device structure according to an embodiment of the present disclosure;

FIG. 18 is a schematic flowchart of a method for preparing a thin film transistor film layer according to an embodiment of the present disclosure;

FIG. 19 is a schematic flowchart showing the preparation of a substrate layer in the method for preparing the thin film transistor film layer according to an embodiment of the present disclosure;

FIG. 20 is a schematic flowchart showing the preparation of an oxide semiconductor structure on a side, away from a first gate structure, of a part of the first buffer layer which is disposed in a first region, in the method for preparing the thin film transistor film layer according to an embodiment of the present disclosure;

FIG. 21 is a schematic flowchart showing the preparation of a second source-drain structure on a side of the first insulating layer away from the first buffer layer in the method for preparing the thin film transistor film layer according to an embodiment of the present disclosure;

FIG. 22 is a schematic flowchart of an extended method of the method for preparing the thin film transistor film layer according to an embodiment of the present disclosure;

FIG. 23 is a schematic structural diagram showing film layers after the substrate layer is prepared in the extended method of preparing the thin film transistor film layer according to an embodiment of the present disclosure;

FIG. 24 is a schematic structural diagram showing film layers after a first gate structure is prepared on a side of a first portion of the substrate layer which is disposed in a first region and a first buffer layer is prepared on the substrate layer and on a side of the first gate structure away from the substrate layer, in an extended method of preparing the thin film transistor film layer according to an embodiment of the present disclosure;

FIG. 25 is a schematic structural diagram showing film layers after a first source-drain structure disposed in the first region and a third source-drain structure of a polysilicon device structure disposed in a second region are prepared on the side of the first buffer layer away from the substrate layer, and the third source-drain structure is enabled to be electrically connected to the polysilicon structure, in an extended method of the method for preparing the thin film transistor film layer according to an embodiment of the present disclosure;

FIG. 26 is a schematic structural diagram showing film layers after a sacrificial layer is coated on the first buffer layer, the third source-drain structure and the first source-drain structure in an extended method of the method for preparing the thin film transistor film layer according to an embodiment of the present disclosure;

FIG. 27 is a schematic structural diagram showing film layers after a photoresist structure is prepared on the sacrificial layer in an extended method of the method for preparing the thin film transistor film layer according to an embodiment of the present disclosure;

FIG. 28 is a schematic structural diagram showing film layers after a part of the sacrificial layer is stripped off by taking the photoresist structure as a mask, to expose a part of the first source-drain structure and a part of the first buffer layer in an extended method of the method for preparing the thin film transistor film layer according to an embodiment of the present disclosure;

FIG. 29 is a schematic structural diagram showing film layers after an oxide semiconductor layer is deposited on the photoresist structure, the exposed part of the first source-drain structure and the exposed part of the first buffer layer in an extended method of the method for preparing the thin film transistor film layer according to an embodiment of the present disclosure;

FIG. 30 is a schematic structural diagram showing film layers after the remaining sacrificial layer is stripped off to obtain the oxide semiconductor structure which is in contact with a part of the first source-drain structure in an extended method of the method for preparing the thin film transistor film layer according to an embodiment of the present disclosure;

FIG. 31 is a schematic structural diagram showing film layers after a first insulating layer is prepared on a side of the oxide semiconductor structure, a side of the first source-drain structure and a side of the third source-drain structure which are away from the first buffer layer and a second gate structure is prepared on a side, away from the first gate structure, of a part of the first insulating layer which is disposed in the first region, in an extended method of the method for preparing the thin film transistor film layer according to an embodiment of the present disclosure; and

FIG. 32 is a schematic structural diagram showing film layers after a second source-drain structure is prepared on a side of the first insulating layer away from the first buffer layer, and at least part of the second source-drain structure disposed in the first region is enabled to be electrically connected to the other part of the first source-drain structure, and at least part of the second source-drain structure disposed in the second region is enabled to be electrically connected to the third source-drain structure, in an extended method of the method for preparing the thin film transistor film layer according to an embodiment of the present disclosure.

In drawings, reference numerals represent the following:
100—substrate layer; 110a—first region; 100b—second region;
210—first gate structure;
220—first buffer layer;
230—first source-drain structure; 231—first source structure; 232—first drain structure;
240—oxide semiconductor structure;
250—first insulating layer;
260—second gate structure;
270—second insulating layer;
280—second source-drain structure; 281—second source structure; 282—second drain structure;
310—polysilicon structure;
320—third insulating layer;
330—third gate structure;
340—fourth insulating layer;
350—third source-drain structure;
360—planarization layer; 370—anode structure;
400—sacrificial layer; 500—photoresist structure; 600—oxide semiconductor layer.

### DETAILED DESCRIPTION

The present disclosure is described in detail hereinafter. Examples of embodiments of the present disclosure are illustrated in the accompanying drawings. The same or similar reference numerals represent the same or similar components or components with the same or similar functions throughout. In addition, the detailed descriptions of the known technologies which are unnecessary for the illustrated features of the present disclosure are omitted. The embodiments described below with reference to the accompanying drawings are exemplary only, and are only intended to explain the present disclosure, rather than being construed as limitations to the present disclosure.

Those skilled in the art can understand that all terms (including technical and scientific terms) as used herein have the same meanings as commonly understood by those of ordinary skill in the art of the present disclosure, unless otherwise defined. It should also be understood that terms such as those defined in the general dictionary should be understood to have the meanings consistent with the meanings in the context of the prior art, and will not be interpreted to have an idealized or overly formal meaning, unless specifically defined herein.

It can be understood by those skilled in the art that the singular forms “a/an”, “one”, “the”, “said” and “this” may also include plural forms, unless otherwise specified. It should be further understood that the expression “include/comprise” used in the description of the present disclosure means there exists a feature, an integer, a step, an operation, an element and/or a component, but could not exclude the existence or addition of one or more other features, integers, steps, operations, elements, components and/or combinations thereof. The term “and/or” as used herein includes all or any of one or more associated listed items, and any combination thereof.

Several terms involved in the present disclosure are introduced and interpreted first.

LTPS: Low Temperature Poly-Silicon.

LTPO: Low Temperature Polycrystalline Oxide. In a LTPO design, a LTPS device and a LTPO device are disposed in the same controlled unit (such as a pixel), in which the LTPS device is configured to drive the controlled unit, and the LTPO device functions as a switch. That is, two types of thin film transistor (TFT) devices, i.e., the LTPS device and the LTPO device are integrated in the same controlled unit.

The inventors of the present disclosure have conducted researches and found that, in an OLED product, a LTPO backplane drive circuit, that is, a backplane structure that integrates the LTPS device and the LTPO device, may be used to reduce power consumption. In an exemplary embodiment, the LTPS device is used as a driving TFT of an OLED element, and the LTPO device is used as a switching TFT. In this way, a current source is supplied to an OLED for display by taking advantage of the characteristics of fast response speed and large turn-on current of the LTPS device, and meanwhile the power consumption of the back plate drive circuit is reduced by taking advantage of the characteristic of low electric leakage of the LTPO device.

However, in the LTPO structure, due to certain compatibility of the overall back plate process, the stability of an oxide semiconductor structure which functions as a channel in the LTPO device is not high, which leads to the insufficient stability of a LTPO driving circuit. For example, the source-drain structure disposed on the upper layer of the oxide semiconductor structure and the oxide semiconductor structure are overlapped through via holes in an intermediate film layer between the source-drain structure and the oxide semiconductor structure. However, in the process of etching the intermediate film layer to obtain the via holes, the etching gases are inevitably to be in contact with the surface layer of the oxide semiconductor structure. Due to the uneven thickness of the intermediate film layer or an error in the etching process, over-etching is likely to occur very easily, which leads to damage to the surface of the oxide semiconductor structure, to affect the leakage current and stability of the oxide semiconductor structure. In addition, oxygen, chlorine, fluorine, and the like in the etching gases enters the oxide semiconductor structure, resulting in a defect state of the oxide semiconductor structure, which also affects the leakage current and stability of the oxide semiconductor structure.

The switching device structure and the method for preparing the same, the thin film transistor film layer and the display panel provided by the present disclosure aim to solve the above technical problems in the prior art.

The technical solutions of the present disclosure and how the technical solutions of the present disclosure solve the above technical problems are described in detail below in conjunction with exemplary embodiments.

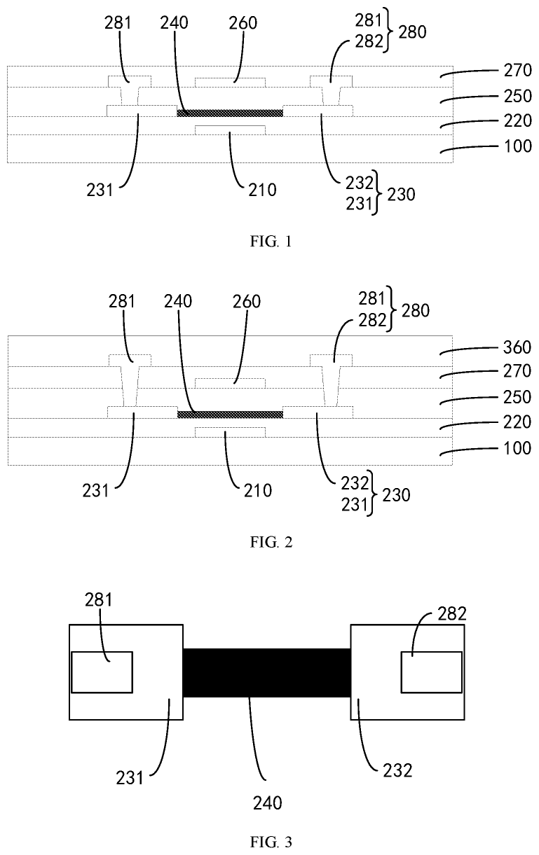

An embodiment of the present disclosure provides a switching device structure. The schematic structural diagrams of the switching device structure are shown in FIG. 1 to FIG. 5. The switching device structure includes a first gate structure 210, a first buffer layer 220, a first source-drain structure 230, an oxide semiconductor structure 240, a first insulating layer 250, a second gate structure 260 and a second source-drain structure 280.

The first gate structure 210 is disposed on a side of a substrate layer 100.

The first buffer layer 220 is disposed on a side of the first gate structure 210 and a side of the substrate layer 100, and the first gate structure 210 is disposed between the substrate layer 100 and the first buffer layer 220.

The first source-drain structure 230 is disposed on the side of the first buffer layer 220 away from the substrate layer 100.

The oxide semiconductor structure 240 is also disposed on the side of the first buffer layer 220 away from the substrate layer 100, and is in contact with a part of the first source-drain structure 230.

The first insulating layer 250 is disposed on the side of the first source-drain structure 230 and the side of the oxide semiconductor structure 240 which are away from the first buffer layer 220.

The second gate structure 260 is disposed on the side of the first insulating layer 250 away from the first buffer layer 220.

The second source-drain structure 280 is disposed on the side of the first insulating layer 250 away from the first buffer layer 220, and is electrically connected to the other part of the first source-drain structure 230.

In the present embodiment, the first gate structure 210, the first source-drain structure 230, the oxide semiconductor structure 240, the second gate structure 260, and the second source-drain structure 280 constitute the main functional film layers of the LTPO device structure.

The switching device structure provided in this embodiment adopts the LTPO structure, which has the advantage of low electric leakage and can effectively reduce the power consumption. In the switching device structure, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can effectively prevent damage to the surface of the oxide semiconductor structure 240 during the preparing process or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

Optionally, projections of the first gate structure 210, the oxide semiconductor structure 240 and the second gate structure 260 on the substrate layer 100 are at least partially overlapped. The projection here refers to the orthographic projection on the surface of the substrate layer 100. Projections of any two of the first gate structure 210, the oxide semiconductor structure 240 and the second gate structure 260 on the substrate layer 100 are at least partially overlapped.

Optionally, as shown in FIG. 1, each of the second source-drain structure 280 and the second gate structure 260 may be in contact with the side of the first insulating layer 250 away from the first buffer layer 220. That is, the second source-drain structure 280 and the second gate structure 260 are disposed in the same layer, and only need to be insulated from each other, for example, the second source-drain structure 280 and the second gate structure 260 are spaced apart from each other. In this way, thinning of the film layer of the device is facilitated.

As shown in FIG. 1, the switching device structure further includes a second insulating layer 270. The second insulating layer 270 is disposed on the side of the second gate structure 260, the side of the second source-drain structure 280 and the side of the first insulating layer 250 which are away from the first buffer layer 220.

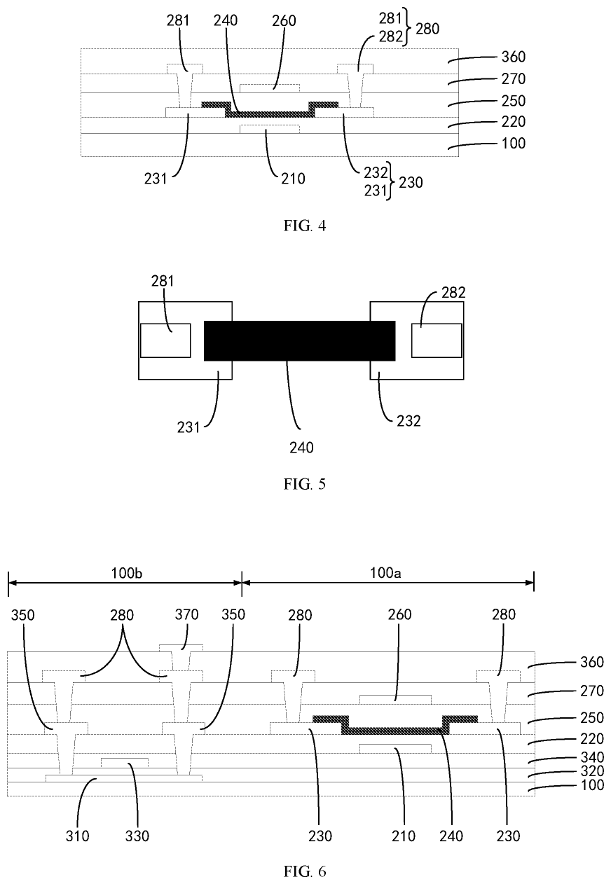

Optionally, as shown in FIG. 2 and FIG. 4, the switching device structure further includes a second insulating layer 270. The second insulating layer 270 is disposed on the side of the second gate structure 260 and the side of the first insulating layer 250 which are away from the first buffer layer 220. That is, the second source-drain structure 280 and the second gate structure 260 are disposed in different layers, and the second source-drain structure 280 and the second gate structure 260 are insulated and spaced apart by the second insulating layer 270, which facilitates improvement of insulation.

Optionally, as shown in FIG. 2 and FIG. 4, the switching device structure further includes a planarization layer 360. The planarization layer 360 is disposed on the side of the second insulating layer 270 and the side of the second source-drain structure 280 which are away from the first insulating layer 250. The planarization layer 360 may be used for the insulation of the second source-drain structure 280 on the one hand, and may facilitate the preparation of subsequent film layers on the other hand.

In some possible implementations, as shown in FIG. 1 to FIG. 5, the first source-drain structure 230 includes a first source structure 231 and a first drain structure 232 that are separated from each other.

One end of the oxide semiconductor structure 240 is connected to a part of the first source structure 231, and the other end of the oxide semiconductor structure 240 is connected to a part of the first drain structure 232.

The second source-drain structure 280 includes a second source structure 281 and a second drain structure 282 that are separated from each other. The second source structure 281 is electrically connected to the other part of the first source structure 231, and the second drain structure 282 is electrically connected to the other part of the first drain structure 232.

In this embodiment, the first source structure 231 is used as a bridge between the second source structure 281 and one end of the oxide semiconductor structure 240, and the first drain structure 232 is used as a bridge between the second drain structure 282 and the other end of the oxide semiconductor structure 240, such that the via hole electrically connected to the second source structure 281 and the via hole electrically connected to the second drain structure 282 are not in direct contact with the oxide semiconductor structure 240, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

In some possible implementations, the first source structure 231, the first drain structure 232 and at least part of the oxide semiconductor structure 240 are in contact with the first buffer layer 220.

Optionally, the first source structure 231, the first drain structure 232, and the entire oxide semiconductor structure 240 are in contact with the first buffer layer 220, which facilitates the thinning of the film layer of the device.

As shown in FIG. 2 and FIG. 3, in some implementations, two ends of the oxide semiconductor structure 240 are respectively connected to a sidewall of the first source structure 231 and a sidewall of the first drain structure 232. It should be noted that the shapes of the first source structure 231, the first drain structure 232, and the semiconductor structure 240 in FIG. 3 and FIG. 5 are exemplary only. The first source structure 231, the first drain structure 232, and the semiconductor structure 240 may be of other regular or irregular shapes.

As shown in FIG. 4 and FIG. 5, in another implementation, the projection of one end of the oxide semiconductor structure 240 on the substrate layer 100 overlaps with the projection of a part of the first source structure 231 on the substrate layer 100, and the projection of the other end of the oxide semiconductor structure 240 on the substrate layer 100 overlaps with the projection of a part of the first drain structure 232 on the substrate layer 100. In this way, the contact area between the oxide semiconductor structure 240 and the first source structure 231 and the contact area between the oxide semiconductor structure 240 and the first drain structure 232 can be increased, which can enhance the effectiveness of electrical connection.

Optionally, as shown in FIG. 4 and FIG. 5, one end of the oxide semiconductor structure 240 is disposed on the side of a part of the first source structure 231 away from the first buffer layer 220. In this way, the oxide semiconductor structure 240 may be prepared after the first source structure 231 is prepared in the preparation process, and one end of the oxide semiconductor structure 240 covers a part of the first source structure 231.

Optionally, as shown in FIG. 4 and FIG. 5, the other end of the oxide semiconductor structure 240 is disposed on the side of a part of the first drain structure 232 away from the first buffer layer 220. In this way, the oxide semiconductor structure 240 may be prepared after the first drain structure 232 is prepared in the preparation process, and the other end of the oxide semiconductor structure 240 covers a part of the first drain structure 232.

Optionally, one end of the oxide semiconductor structure 240 is disposed on the side of a part of the first source structure 231 away from the first buffer layer 220, and the other end of the oxide semiconductor structure 240 is disposed on the side of a part of the first drain structure 232 away from the first buffer layer 220. In this way, the oxide semiconductor structure 240 may be prepared after the first source structure 231 and the first drain structure 232 are prepared in the preparation process, one end of the oxide semiconductor structure 240 covers a part of the first source structure 231, and the other end of the oxide semiconductor structure 240 covers a part of the first drain structure 232.

Based on the same inventive concept, an embodiment of the present disclosure provides a thin film transistor film layer. The schematic structural diagram of the thin film transistor film layer is shown in FIG. 6. The thin film transistor film layer includes a polysilicon device structure and any of the switching device structures provided in the above embodiments.

The polysilicon device structure includes a polysilicon structure 310, a third insulating layer 320, a third gate structure 330, a fourth insulating layer 340, and a third source-drain structure 350 that are sequentially laminated on a side of the substrate layer 100.

The first gate structure 210, the first source-drain structure 230, the oxide semiconductor structure 240, and some of the second source-drain structures 280 in the switching device structure are disposed in a first region 100a of the thin film transistor film layer.

The polysilicon structure 310, the third gate structure 330, the third source-drain structure 350 and others of the second source-drain structures 280 are disposed in a second region 100b of the thin film transistor film layer.

The third source-drain structure 350 is electrically connected to the polysilicon structure 310.

Each of the others of the second source-drain structures 280 is electrically connected to the third source-drain structure 350.

In this embodiment, the thin film transistor film layer adopts a structure integrating the polysilicon device structure and the switching device structure. At least the polysilicon structure 310, the third gate structure 330 and the third source-drain structure 350 constitute the main functional film layers of the LTPS device structure. At least the first gate structure 210, the first source-drain structure 230, the oxide semiconductor structure 240, and the second source-drain structure 280 constitute the main functional film layers of the LTPO device structure.

That is, the thin film transistor film layer provided in this embodiment adopts a LTPO structure that integrates the LTPS device and the LTPO device. The current source may be supplied to the OLED for display by taking advantage of the characteristics of fast response speed and large turn-on current of the LTPS device. Meanwhile, the power consumption of the thin film transistor film layer may be reduced by taking advantage of the characteristic of low electric leakage of the LTPO device. In the LTPO device, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can prevent damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

The thin film transistor film layer provided in this embodiment adopts a structure in which the switching device structure and the polysilicon device structure are disposed in different regions. In an exemplary embodiment, the main functional film layers of the switching device structure are disposed in the first region 100a, and the main functional film layers of the polysilicon device structure are disposed in the second region 100b, such that the switching device structure and the polysilicon device structure can share at least a part of the film layer structure, which can facilitate the thinning of the film layer of the device.

Optionally, the projection of the polysilicon structure 310 on the substrate layer 100 at least partially overlaps with the projection of the third gate structure 330 on the substrate layer 100.

In some possible implementations, as shown in FIG. 6, the third source-drain structure 350 and the first source-drain structure 230 of the switching device structure are both disposed on the side of the first buffer layer 220 away from the substrate layer 100, and are in contact with the first buffer layer 220.

In this embodiment, the third source-drain structure 350 and the first source-drain structure 230 of the switching device structure may be disposed in the same layer, as long as the third source-drain structure 350 and the first source-drain structure 230 of the switching device structure are insulated from each other, for example, being spaced apart from each other, which can facilitate the thinning of the film layer of the device, and also facilitate the combination of the preparation process of the third source-drain structure 350 and the preparation process of the first source-drain structure 230. For example, after the first source-drain layer is deposited on the side of the first buffer layer 220 away from the substrate layer 100, and the first source-drain layer is patterned to obtain both the third source-drain structure 350 and the first source-drain structure 230. That is, the third source-drain structure 350 and the first source-drain structure 230 are obtained by a one-time patterning process.

In some possible implementations, as shown in FIG. 6, the third gate structure 330 is disposed on the side of the third insulating layer 320 away from the substrate layer 100.

The fourth insulating layer 340 is disposed on the side of the third gate structure 330 and the side of the third insulating layer 320 which are away from the substrate layer 100.

The first gate structure 210 is disposed on the side of the fourth insulating layer 340 away from the third insulating layer 320.

The first buffer layer 220 is disposed on the side of the first gate structure and the side of the fourth insulating layer 340 which are away from the third insulating layer 320.

In this embodiment, the third gate structure 330 and the first gate structure 210 are disposed in different layers and are spaced apart by the fourth insulating layer 340, which can further ensure the insulation between the third gate structure 330 and the first gate structure 210.

In some possible implementations, at least some of the others of the second source-drain structures 280 are configured to be electrically connected to the anode layer. In this way, the thin film transistor film layer can drive an OLED display module.

In some possible implementations, the substrate layer 100 includes a second buffer layer.

Optionally, the polysilicon structure 310 is disposed on a side of the second buffer layer and is in contact with the second buffer layer.

Based on the same inventive concept, an embodiment of the present disclosure provides a display panel. The display panel includes any of the thin film transistor film layers provided in the aforesaid embodiments, an anode layer, a light-emitting layer and a cathode layer which are sequentially laminated.

At least some of the others of the second source-drain structures 280 of the thin film transistor film layer are electrically connected to the anode layer.

In this embodiment, the thin film transistor film layer in the display panel adopts a LTPO structure that integrates the LTPS device and the LTPO device. The current source may be supplied to the OLED display module of the display panel by taking advantage of the characteristics of fast response speed and large turn-on current of the LTPS device. Meanwhile, the power consumption of the thin film transistor film layer may be reduced by taking advantage of the characteristic of low electric leakage of the LTPO device. In the LTPO device, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can prevent the damage to the surface of the oxide semiconductor structure 240 during the preparing process, or the defect state of the oxide semiconductor structure 240. Therefore, the stability of the oxide semiconductor structure 240 can be effectively improved and the eclectic leakage of the oxide semiconductor structure 240 can be reduced, thereby reducing the power consumption of the entire display panel.

Based on the same inventive concept, an embodiment of the present disclosure provides a display apparatus. The display apparatus includes any of the switching device structures provided in the aforesaid embodiments, or any of the thin film transistor film layers provided in the aforesaid embodiments, or any of the display panels provided in the aforesaid embodiments.

Optionally, the display apparatus may be a TV, a digital photo frame, a mobile phone, a smart watch, a tablet computer, or the like, or may be a wearable device (such as a smart bracelet, a smart watch, or virtual reality (VR) glasses).

In this embodiment, since the display apparatus adopts any of the switching device structures provided in the aforesaid embodiments, or any of the thin film transistor film layers provided in the aforesaid embodiments, or any of the display panels provided in the aforesaid embodiments, the principles and technical effects of the display apparatus may be made reference to the aforesaid embodiments, and are not be repeated herein.

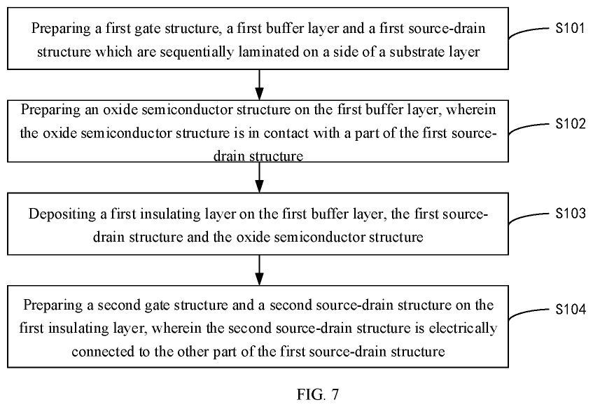

Based on the same inventive concept, an embodiment of the present disclosure provides a method for preparing a switching device structure. The flowchart of this method is shown in FIG. 7. The method includes the following steps S101 to S104.

In S101, a first gate structure, a first buffer layer and a first source-drain structure which are sequentially laminated are prepared on a side of a substrate layer.

In S102, an oxide semiconductor structure is prepared on the first buffer layer. The oxide semiconductor structure is in contact with a part of the first source-drain structure.

In S103, a first insulating layer is deposited on the first buffer layer, the first source-drain structure and the oxide semiconductor structure.

In S104, a second gate structure and a second source-drain structure are prepared on the first insulating layer. The second source-drain structure is electrically connected to the other part of the first source-drain structure.

According to the method for preparing a switching device structure provided in the embodiment of the present disclosure, the oxide semiconductor structure 240 is electrically connected to a part of the first source-drain structure 230, and the second source-drain structure 280 is electrically connected to the other part (i.e., a part that is not connected to the oxide semiconductor structure 240) of the first source-drain structure 230. That is, the first source-drain structure 230 is used as a bridge between the second source-drain structure 280 and the oxide semiconductor structure 240, such that the etching gas is not in contact with the surface layer of the oxide semiconductor structure 240 when a via hole electrically connected to the second source-drain structure 280 is prepared, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

Optionally, the second gate structure 260 and the second source-drain structure 280 may be prepared in the same film layer on the first insulating layer 250, as long as the second gate structure 260 and the second source-drain structure 280 are insulated from each other, such as being spaced apart from each other, which can facilitate the thinning of the film layers of a device. For example, each of the prepared second gate structure 260 and second source-drain structure 280 is in contact with the side of the first insulating layer 250 away from the substrate layer 100.

Optionally, the second gate structure 260 and the second source-drain structure 280 may be prepared in different layers on the first insulating layer 250, which will be described in detail below, and is not repeated herein.

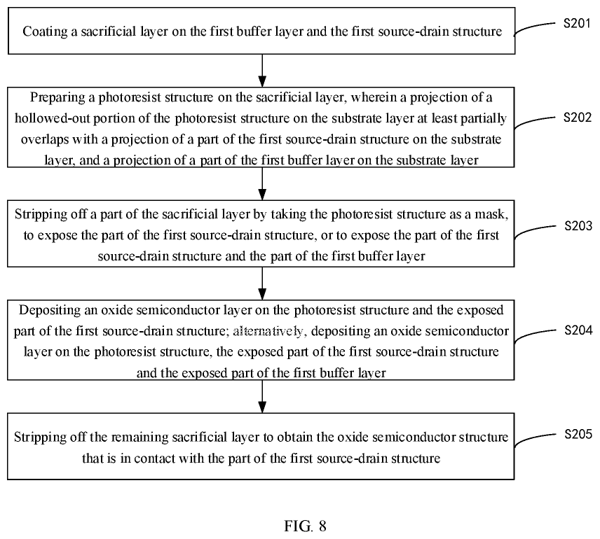

In some possible implementations, in step S102, preparing the oxide semiconductor structure on the first buffer layer includes the following steps S201 to S205 as shown in FIG. 8.

In S201, a sacrificial layer is coated on the first buffer layer and the first source-drain structure.

In S202, a photoresist structure is prepared on the sacrificial layer. The projection of a hollowed-out portion of the photoresist structure on the substrate layer at least partially overlaps with the projection of a part of the first source-drain structure on the substrate layer, and the projection of a part of the first buffer layer on the substrate layer.

In S203, a part of the sacrificial layer is stripped off by taking the photoresist structure as a mask, to expose the part of the first source-drain structure, or to expose the part of the first source-drain structure and the part of the first buffer layer.

In S204, an oxide semiconductor layer is deposited on the photoresist structure and the exposed part of the first source-drain structure. Alternatively, an oxide semiconductor layer is deposited on the photoresist structure, the exposed part of the first source-drain structure and the exposed part of the first buffer layer.

In S205, the remaining sacrificial layer is stripped off to obtain the oxide semiconductor structure that is in contact with the part of the first source-drain structure.

In this embodiment, a part of the sacrificial layer is stripped off by taking the patterned photoresist structure 500 as a mask, such that a part of the oxide semiconductor layer 600 may be directly deposited on the exposed part of the first source-drain structure 230 after the oxide semiconductor layer 600 is deposited. That is, the part of the oxide semiconductor layer 600 is connected to the exposed part of the first source-drain structure 230. Then, the part of the oxide semiconductor layer 600 that is deposited on the photoresist structure 500 previously is also stripped off when the remaining sacrificial layer 400 is stripped off. The remaining part of the oxide semiconductor layer 600 connected to the first source-drain structure 230 is the desired oxide semiconductor structure 240.

Compared with the process of patterning the oxide semiconductor layer 600 by an etching process, the oxide semiconductor layer 600 is patterned by a stripping process in this embodiment, which can avoid the possible influence on the first source-drain structure 230 by the etching process, for example, the damage to the first source-drain structure 230 caused by the etching substance (such as an etching solution).

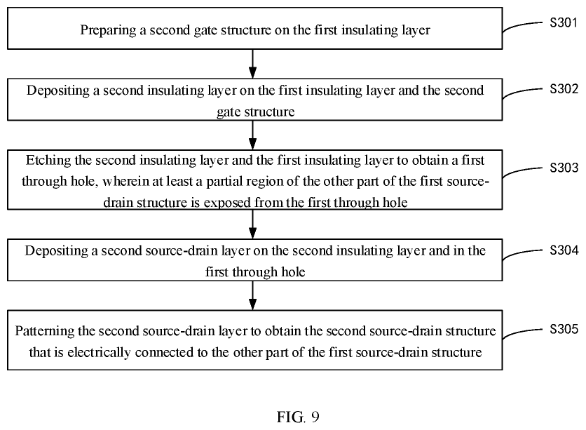

In some possible implementations, in the step S104, preparing the second gate structure and the second source-drain structure on the first insulating layer includes the following steps S301 to S305, as shown in FIG. 9.

In S301, the second gate structure is prepared on the first insulating layer.

In S302, a second insulating layer is deposited on the first insulating layer and the second gate structure.

In S303, the second insulating layer and the first insulating layer are etched to obtain a first through hole, wherein at least a partial region of the other part of the first source-drain structure is exposed from the first through hole.

In S304, a second source-drain layer is deposited on the second insulating layer and in the first through hole.

In S305, the second source-drain layer is patterned to obtain the second source-drain structure that is electrically connected to the other part of the first source-drain structure.

In this embodiment, the second gate structure 260 and the second source-drain structure 280 may be prepared in different layers on the first insulating layer 250. In an exemplary embodiment, the second gate structure 260 and the second source-drain structure 280 are spaced apart by the second insulating layer 270, which can further improve the insulation between the second gate structure 260 and the second source-drain structure 280.

Only a part of the first source-drain structure 230, which is not connected to the oxide semiconductor structure 240, is exposed from the first through hole obtained by etching the second insulating layer 270 and the first insulating layer 250, which can prevent the etching gas from being in contact with the oxide semiconductor structure 240, thereby effectively avoiding the damage to the surface of the oxide semiconductor structure 240 or the defect state of the oxide semiconductor structure 240 caused by the etching gas.

After the second source-drain layer is deposited on the second insulating layer 270, a part of the second source-drain layer enters the first through hole and is in contact with a part of the first source-drain structure 230 exposed from the first through hole, to form a via hole that electrically connects the second source-drain structure 280 and the first source-drain structure 230.

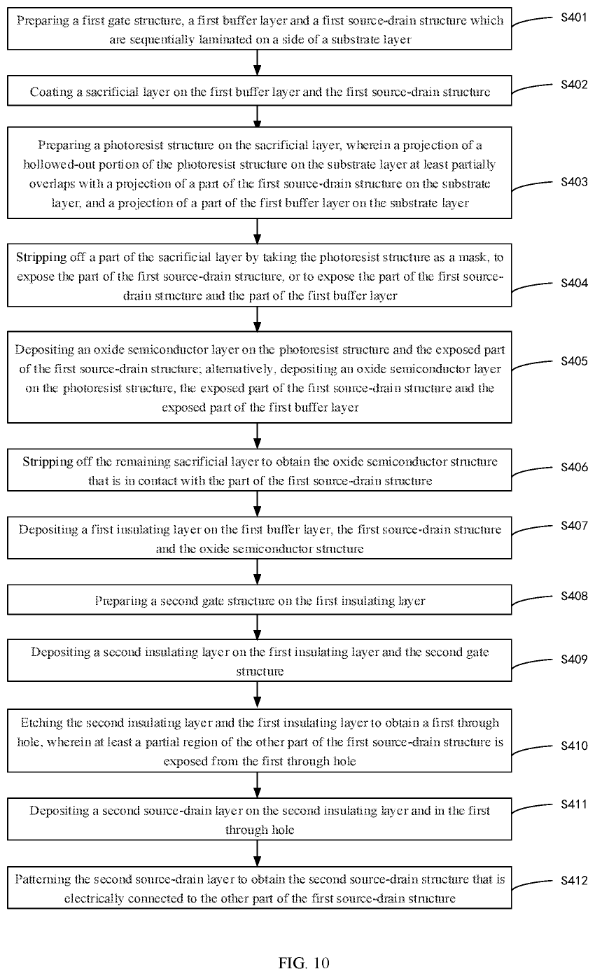

An embodiment of the present disclosure provides an extended method of the method for preparing a switching device structure. The flowchart of this extended method is shown in FIG. 10. The method includes the following steps S401 to S412.

In S401, a first gate structure, a first buffer layer and a first source-drain structure which are sequentially laminated are prepared on a side of a substrate layer.

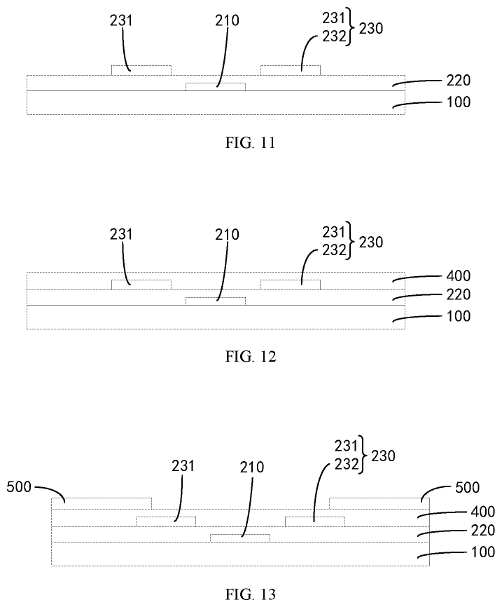

The film layer structure acquired through step S401 is shown in FIG. 11.

Optionally, in step S401, a first gate layer may be deposited on a side of the substrate layer 100 and then the first gate layer is patterned to obtain the first gate structure 210. Next, the first buffer layer 220 is deposited on the substrate layer 100 and on the side of the first gate structure 210 away from the substrate layer 100. Then, a first source-drain layer is deposited on the side of the first buffer layer 220 away from the substrate layer 100, and the first source-drain layer is patterned to obtain the first source-drain structure 230.

Optionally, the first buffer layer 220 may be made of silicon monoxide.

In S402, a sacrificial layer is coated on the first buffer layer and the first source-drain structure.

Here, the sacrificial layer may be made of a lift-off resist (LOR) material.

The film layer structure obtained through step S402 is shown in FIG. 12.

In S403, a photoresist structure is prepared on the sacrificial layer. The projection of a hollowed-out portion of the photoresist structure on the substrate layer at least partially overlaps with the projection of a part of the first source-drain structure on the substrate layer, and the projection of a part of the first buffer layer on the substrate layer.

The film layer structure obtained through step S403 is shown in FIG. 13.

Optionally, in step S403, a photoresist layer may be coated on the side of the sacrificial layer 400 away from the substrate layer 100, and then the photoresist layer is processed by exposure and development processes to obtain the photoresist structure 500.

In S404, a part of the sacrificial layer is stripped off by taking the photoresist structure as a mask, to expose the part of the first source-drain structure, or to expose the part of the first source-drain structure and the part of the first buffer layer.

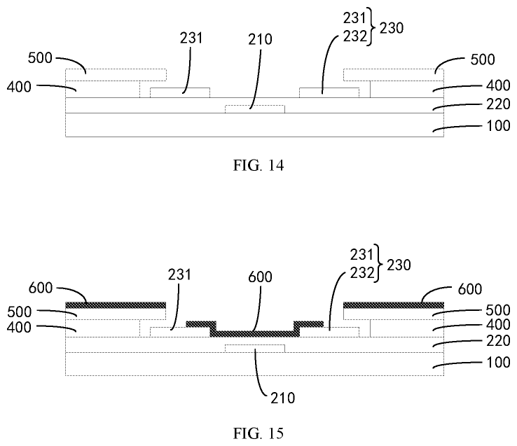

The film layer structure obtained through step S404 is shown in FIG. 14.

Optionally, in step S404, a part of the sacrificial layer 400 may be stripped off by stripping off a developing solution with the photoresist structure 500 as a mask. After stripping and development, the edge of the sacrificial layer 400 is retracted laterally to some extent. This lateral retraction facilitates the fracture between the part of the oxide semiconductor layer 600 subsequently deposited on the first source-drain structure 230 and the part of the oxide semiconductor layer 600 subsequently deposited on the photoresist structure 500.

In S405, an oxide semiconductor layer is deposited on the photoresist structure and the exposed part of the first source-drain structure. Alternatively, an oxide semiconductor layer is deposited on the photoresist structure, the exposed part of the first source-drain structure and the exposed part of the first buffer layer.

The film layer structure obtained through step S405 is shown in FIG. 15.

Since the edge of the sacrificial layer 400 is retracted laterally by stripping and development in step S404, in the oxide semiconductor layer 600 obtained in step S405, the part of the oxide semiconductor layer 600 disposed on the first source-drain structure 230 and the part of the oxide semiconductor layer 600 deposited on the photoresist structure 500 undergo a fracture. This fracture causes a gap to be formed at the edge of the remaining sacrificial layer 400, which can facilitate the contact between the remaining sacrificial layer 400 and the lift-off developer solution in the subsequent process, so as to smoothly strip off the remaining sacrificial layer 400.

Optionally, the oxide semiconductor layer 600 may be made of an indium gallium zinc oxide (IGZO) material.

In S406, the remaining sacrificial layer is stripped off to obtain the oxide semiconductor structure that is in contact with the part of the first source-drain structure.

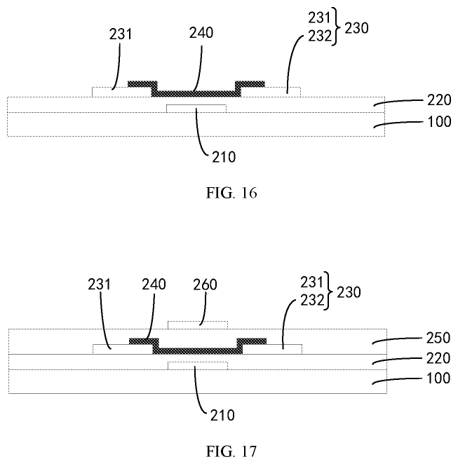

After step S406, the sacrificial layer 400 is stripped off, such that the sacrificial layer 400, the photoresist structure 500 disposed on the sacrificial layer 400, and the part of the oxide semiconductor layer 600 disposed on the sacrificial layer are all stripped off, and the obtained film layer structure is shown in FIG. 16.

Through steps S402 to S406, the oxide semiconductor layer 600 is patterned by a stripping process to obtain the oxide semiconductor structure 240 configured to form a channel.

In S407, a first insulating layer is deposited on the first buffer layer, the first source-drain structure and the oxide semiconductor structure.

Optionally, the first insulating layer 250 may be made of silicon monoxide.

In S408, a second gate structure is prepared on the first insulating layer.

The film layer structure acquired through steps S407 to S408 is shown in FIG. 17.

Optionally, in step S408, a second gate layer may be deposited on the side of the first insulating laver 250 away from the substrate layer 100, and then the second gate layer is patterned to obtain the second gate structure 260.

Optionally, the projection of the second gate structure 260 on the substrate layer 100 at least partially overlaps with the projection of the first gate structure 210 on the substrate layer 100.

In S409, a second insulating layer is deposited on the first insulating layer and the second gate structure.

In S410, the second insulating layer and the first insulating layer are etched to obtain a first through hole, wherein at least a partial region of the other part of the first source-drain structure is exposed from the first through hole.

In S411, a second source-drain layer is deposited on the second insulating layer and in the first through hole.

In S412, the second source-drain layer is patterned to obtain the second source-drain structure that is electrically connected to the other part of the first source-drain structure.

The film layer structure obtained through steps S409 to S412 is shown in FIG. 2 or FIG. 4. That is, a switching device structure provided by the embodiment of the present disclosure is acquired.

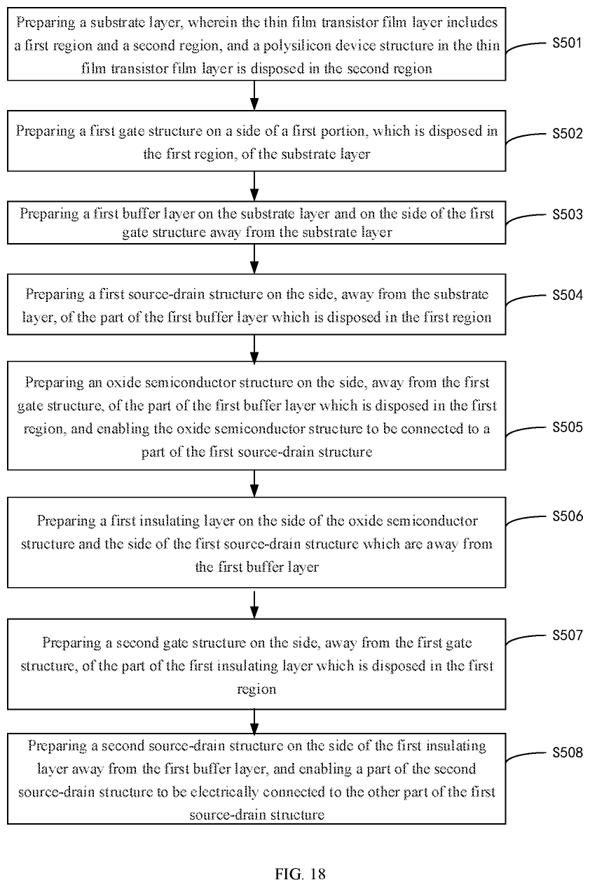

Based on the same inventive concept, an embodiment of the present disclosure provides a method for preparing a thin film transistor film layer. The flowchart of this method is shown in FIG. 18. The method includes the following steps S501 to S508.

In S501, a substrate layer is prepared. The thin film transistor film layer includes a first region and a second region. The polysilicon device structure in the thin film transistor film layer is disposed in the second region.

In S502, a first gate structure is prepared on a side of a first portion, which is disposed in the first region, of the substrate layer.

In S503, a first buffer layer is prepared on the substrate layer and on the side of the first gate structure away from the substrate layer.

In S504, a first source-drain structure is prepared on the side, away from the substrate layer, of the part of the first buffer layer which is disposed in the first region.

In S505, an oxide semiconductor structure is prepared on the side, away from the substrate layer, of the part of the first buffer layer which is disposed in the first region, and the oxide semiconductor structure is enabled to be connected to a part of the first source-drain structure.

In S506, a first insulating layer is prepared on the side of the oxide semiconductor structure and the side of the first source-drain structure which are away from the first buffer layer.

In S507, a second gate structure is prepared on the side, away from the first gate structure, of the part of the first insulating layer which is disposed in the first region.

In S508, a second source-drain structure is prepared on the side of the first insulating layer away from the first buffer layer, and a part of the second source-drain structure is enabled to be electrically connected to the other part of the first source-drain structure.

According to the method for preparing the thin film transistor film layer provided by this embodiment of the present disclosure, a LTPO device structure of the thin film transistor film layer is prepared in the first region of the thin film transistor film layer, and the polysilicon device structure is prepared in the second region of the thin film transistor film layer. That is, the thin film transistor film layer that integrates the polysilicon device structure and the LTPO device may be prepared. In this way, the current source can be supplied to the OLED for display by taking advantage of the characteristics of fast response speed and large turn-on current of the LTPS device. Meanwhile, the power consumption of the thin film transistor film layer is reduced by taking advantage of the characteristic of low electric leakage of the LTPO device.

In this embodiment, at least the prepared first gate structure 210, first source-drain structure 230, oxide semiconductor structure 240, and second source-drain structure 280 constitute the main functional film layers of the LTPO device structure. In the process of preparing the LTPO device structure, the oxide semiconductor structure 240 may be electrically connected to a part of the first source-drain structure 230, and the second source-drain structure 280 is electrically connected to the other part (i.e., a part that is not connected to the oxide semiconductor structure 240) of the first source-drain structure 230. That is, the first source-drain structure 230 is used as a bridge between the second source-drain structure 280 and the oxide semiconductor structure 240, such that the etching gas is not in direct contact with the surface layer of the oxide semiconductor structure 240 when the via hole electrically connected to the second source-drain structure 280 is prepared, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

Optionally, the second gate structure 260 and the second source-drain structure 280 may be prepared in the same film layer on the first insulating layer 250, as long as the second gate structure 260 and the second source-drain structure 280 are insulated from each other, such as being spaced apart from each other, which can facilitate the thinning of the film layer of a device. For example, each of the prepared second gate structure 260 and second source-drain structure 280 is in contact with the side of the first insulating layer 250 away from the substrate layer 100.

Optionally, the second gate structure 260 and the second source-drain structure 280 may be prepared in different film layers on the first insulating layer 250, which is described in detail below, and not be repeated here.

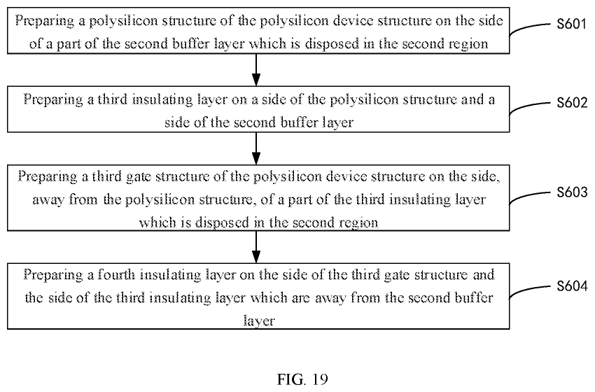

In some possible implementations, in step S501, preparing the substrate layer includes the following steps S601 to S604, as shown in FIG. 19.

In S601, a polysilicon structure of the polysilicon device structure is prepared on the side of a part of the second buffer layer which is disposed in the second region.

In S602, a third insulating layer is prepared on a side of the polysilicon structure and a side of the second buffer layer.

In S603, a third gate structure of the polysilicon device structure is prepared on the side, away from the polysilicon structure, of a part of the third insulating layer which is disposed in the second region.

In S604, a fourth insulating layer is prepared on the side of the third gate structure and the side of the third insulating layer which are away from the second buffer layer.

In this embodiment, the polysilicon structure 310 and the third gate structure 330 in the polysilicon device structure are prepared in the second region 100b, and the third insulating layer 320 is prepared between the polysilicon structure 310 and the third gate structure 330, to improve the insulation between the polysilicon structure 310 and the third gate structure 330. The fourth insulating layer 340 is also prepared on the third gate structure 330 to improve the insulation between the third gate structure 330 and the subsequent conductive structure film layer.

In some possible implementations, at the same time of preparing the first source-drain structure on the side, away from the substrate layer, of the part of the first buffer layer which is disposed in the first region, the above step S504 further includes: preparing a third source-drain structure 350 of the polysilicon device structure on the side, away from the substrate layer 100, of the part of the first buffer layer 220 which is disposed in the second region 100b, and the third source-drain structure 350 is enabled to be electrically connected to the polysilicon structure 310.

In this embodiment, the first source-drain structure 230 of the LTPO device structure and the third source-drain structure 350 of the polysilicon device structure are prepared simultaneously on the side of the first buffer layer 220 away from the substrate layer 100. In an exemplary embodiment, the first source-drain structure 230 is prepared in the first region 100a, and the third source-drain structure 350 is prepared in the second region 100b, which facilitates the combination of the preparation process of the first source-drain structure 230 and the preparation process of the third source-drain structure 350 to shorten the preparation process, and also facilitates the arrangement of the first source-drain structure 230 and the third source-drain structure 350 in the same layer to facilitate the thinning of the thin film transistor film layer.

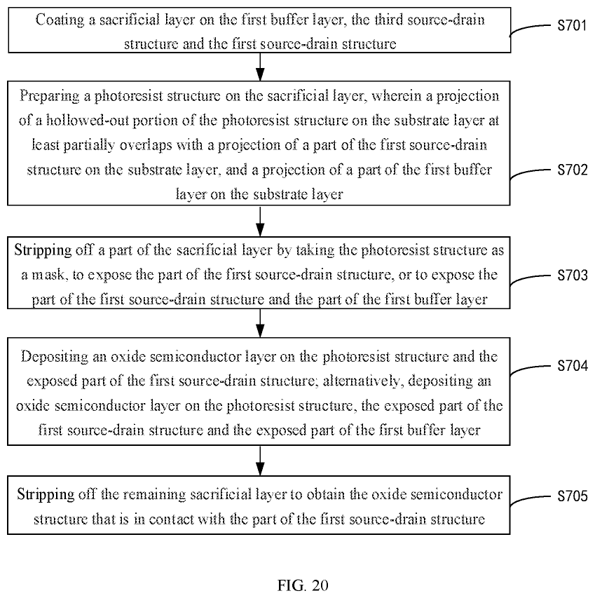

In some possible implementations, in step S505, preparing the oxide semiconductor structure on the side, away from the first gate structure, of the part of the first buffer layer which is disposed in the first region includes the following steps S701 to S705, as shown in FIG. 20.

In S701, a sacrificial layer is coated on the first buffer layer, the third source-drain structure and the first source-drain structure.

In S702, a photoresist structure is prepared on the sacrificial layer. The projection of a hollowed-out portion of the photoresist structure on the substrate layer at least partially overlaps with the projection of a part of the first source-drain structure on the substrate layer, and the projection of a part of the first buffer layer on the substrate layer.

In S703, a part of the sacrificial layer is stripped off by taking the photoresist structure as a mask, to expose the part of the first source-drain structure, or to expose the part of the first source-drain structure and the part of the first buffer layer.

In S704, an oxide semiconductor layer is deposited on the photoresist structure and the exposed part of the first source-drain structure. Alternatively, an oxide semiconductor layer is deposited on the photoresist structure, the exposed part of the first source-drain structure and the exposed part of the first buffer layer.

In S705, the remaining sacrificial layer is stripped off to obtain the oxide semiconductor structure that is in contact with the part of the first source-drain structure.

In this embodiment, a part of the sacrificial layer is stripped off by taking the patterned photoresist structure 500 as a mask, such that a part of the oxide semiconductor layer 600 may be directly deposited on the exposed part of the first source-drain structure 230 after the oxide semiconductor layer 600 is deposited. That is, the part of the oxide semiconductor layer 600 is connected to the exposed part of the first source-drain structure 230. Then, the part of the oxide semiconductor layer 600 which is deposited on the photoresist structure 500 previously is also stripped off when the remaining sacrificial layer 400 is stripped off. The remaining part of the oxide semiconductor layer 600 connected to the first source-drain structure 230 is the desired oxide semiconductor structure 240.

Compared with the process of patterning the oxide semiconductor layer 600 by an etching process, the oxide semiconductor layer 600 is patterned by a stripping process in this embodiment, which can avoid the possible influence on the first source-drain structure 230 due to the compatibility reason, for example, the possible damage to the first source-drain structure 230 caused by the etching substance (such as an etching solution).

In some possible implementations, in the above step S506, preparing the first insulating layer on the side of the oxide semiconductor structure and the side of the first source-drain structure which are away from the first buffer layer includes: preparing the first insulating layer 250 on the side of the oxide semiconductor structure 240, the side of the first source-drain structure 230 and the side of the third source-drain structure 350 which are away from the first buffer layer 220.

In this embodiment, the first insulating layer 250 is used as a shared insulating film layer of the LTPO device structure disposed in the first region 100a and the polysilicon device structure disposed in the second region 100b, which may simplify or shorten the preparing process of the thin film transistor film layer, as well as make the thin film transistor film layer thinner.

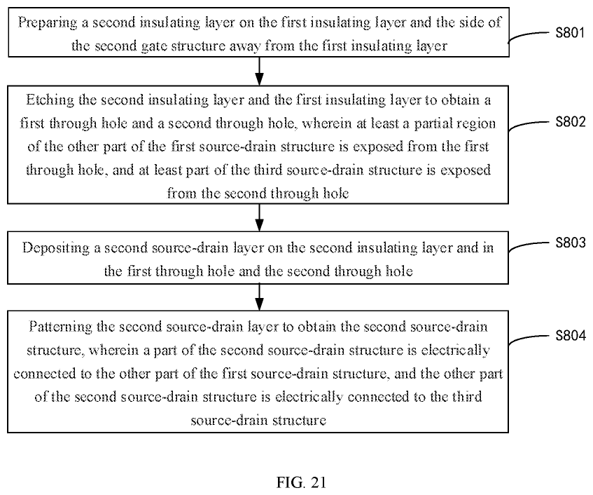

In some possible implementations, in the above step S508, preparing the second source-drain structure on the side of the first insulating layer away from the first buffer layer includes the following steps S801 to S804, as shown in FIG. 21.

In S801, a second insulating layer is prepared on the first insulating layer and the side of the second gate structure away from the first insulating layer.

In S802, the second insulating layer and the first insulating layer are etched to obtain a first through hole and a second through hole, wherein at least a partial region of the other part of the first source-drain structure is exposed from the first through hole, and at least part of the third source-drain structure is exposed from the second through hole.

In S803, a second source-drain layer is deposited on the second insulating layer and in the first through hole and the second through hole.

In S804, the second source-drain layer is patterned to obtain the second source-drain structure. A part of the second source-drain structure is electrically connected to the other part of the first source-drain structure, and the other part of the second source-drain structure is electrically connected to the third source-drain structure.

In this embodiment, the second source-drain structure 280 of the LTPO device structure and the third source-drain structure 350 of the polysilicon device structure are prepared at the same time on a side of the first insulating layer 250 and the side of the second gate structure 260 away from the first insulating layer 250, which facilitates the combination of the preparation process of the third source-drain structure 350 and the preparation process of the second source-drain structure 280, to shorten the manufacturing process, and meanwhile facilitates the arrangement of the third source-drain structure 350 and the first source-drain structure 230 in the same layer, to make the thin film transistor film layer thinner, as long as they are insulated from each other, e.g., spaced apart from each other in the patterning process.

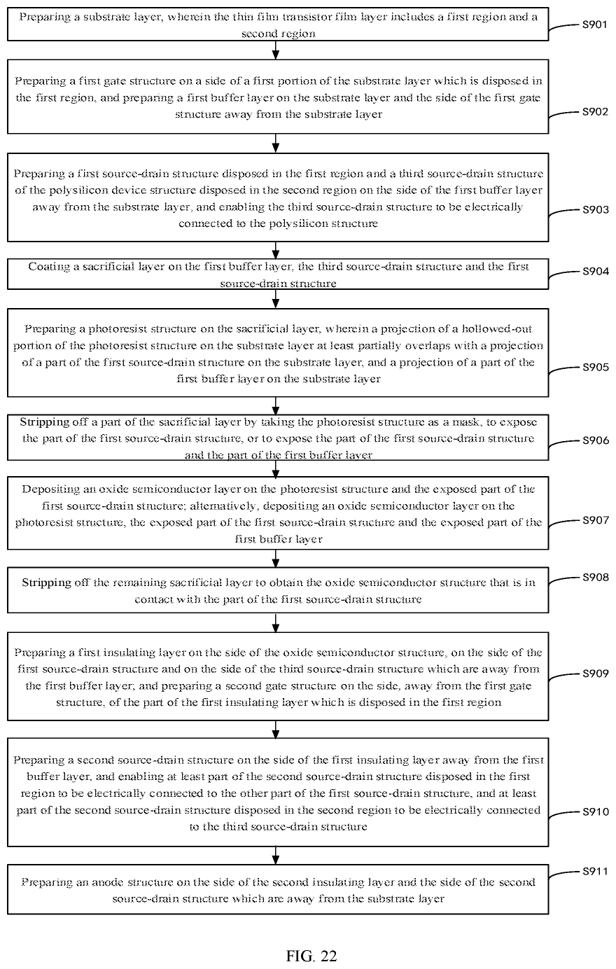

An embodiment of the present disclosure provides an extended method of the method for preparing a thin film transistor film layer. The thin film transistor film layer includes a first region and a second region. The schematic flowchart of this method includes the following steps S901 to S912, as shown in FIG. 22.

In S901, a substrate layer is prepared. The thin film transistor film layer includes a first region and a second region.

Optionally, the polysilicon device structure in the thin film transistor film layer is disposed in the second region.

The film layer structure obtained through step S901 is shown in FIG. 23.

Optionally, in step S901, a polysilicon structure 310 of the polysilicon device structure may be first prepared on the side of the second buffer layer disposed in the second region 100b. Next, a third insulating layer 320 is prepared on a side of the polysilicon structure 310 and on a side of the second buffer layer. Then, a third gate structure 330 of the polysilicon device structure is prepared on the side, away from the polysilicon structure 310, of a part of the third insulating layer 320 which is disposed in the second region 100b. Afterwards, a fourth insulating layer 340 is prepared on the side of the third gate structure 330 and the side of the third insulating layer 320 which are away from the second buffer layer.

Optionally, the third insulating layer 320 completely covers the first region 100a and the second region 100b of the thin film transistor film layer, and is in contact with the side of the polysilicon structure 310 and the side of the second buffer layer which are away from the substrate layer 100.

Optionally, the projection of the second gate structure 260 on the substrate layer 100 at least partially overlaps with the projection of the first gate structure 210 on the substrate layer 100.

In S902, a first gate structure is prepared on a side of a first portion of the substrate layer which is disposed in the first region, and a first buffer layer is prepared on the substrate layer and the side of the first gate structure away from the substrate layer.

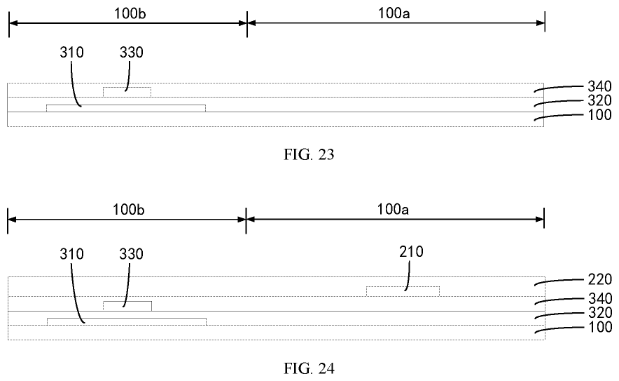

The film layer structure obtained through step S902 is shown in FIG. 24.

Optionally, in step S902, a first gate layer may be deposited on the side of the fourth insulating layer 340 away from the substrate layer 100. Next, the first gate layer is patterned to obtain the first gate structure 210 of the LTPO device structure. The first buffer layer 220 is then deposited on the fourth insulating layer 340 and the first gate structure 210.

Optionally, the first buffer layer 220 completely covers the first region 100a and the second region 100b of the thin film transistor film layer, and is in contact with the side of the first gate structure 210 and the side of the fourth insulating layer 340 which are away from the substrate layer 100.

Optionally, the first buffer layer 220 may be made of silicon monoxide.

In S903, a first source-drain structure disposed in the first region and a third source-drain structure of the polysilicon device structure disposed in the second region are prepared on the side of the first buffer layer away from the substrate layer, and the third source-drain structure is electrically connected to the polysilicon structure.

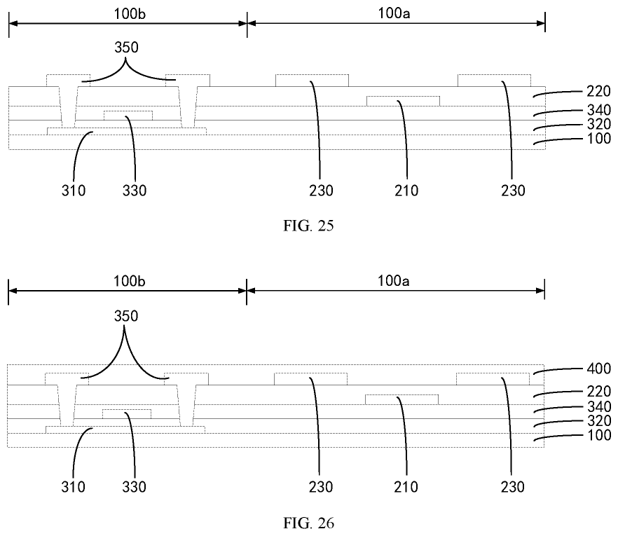

The film layer structure obtained through step S903 is shown in FIG. 25.

Optionally, in step S903, the part of the first buffer layer 220 disposed in the second region 100b may be etched first, to obtain a third though hole from which a part of the polysilicon structure 310 is exposed. Next, a first source-drain layer is deposited on the first buffer layer 220 and in the third through hole. The first source-drain layer is then patterned to obtain the first source-drain structure 230 disposed in the first region 100a and the third source-drain structure 350 of the polysilicon device structure disposed in the second region 100b. The third source-drain structure 350 is electrically connected to the polysilicon structure 310.

Optionally, each of the first source-drain structure 230 and the third source-drain structure 350 is in contact with the side of the first buffer layer 220 away from the substrate layer 100.

In S904, a sacrificial layer is coated on the first buffer layer, the third source-drain structure and the first source-drain structure.

The film layer structure obtained through step S904 is shown in FIG. 26.

Optionally, the sacrificial layer 400 completely covers the first region 100a and the second region 100b of the thin film transistor film layer, and is in contact with the side of the first buffer layer 220, the side of the third source-drain structure 350 and the side of the first source-drain structure 230 away from the substrate layer 100.

In S905, a photoresist structure is prepared on the sacrificial layer. The projection of a hollowed-out portion of the photoresist structure on the substrate layer at least partially overlaps with the projection of a part of the first source-drain structure on the substrate layer, and the projection of a part of the first buffer layer on the substrate layer.

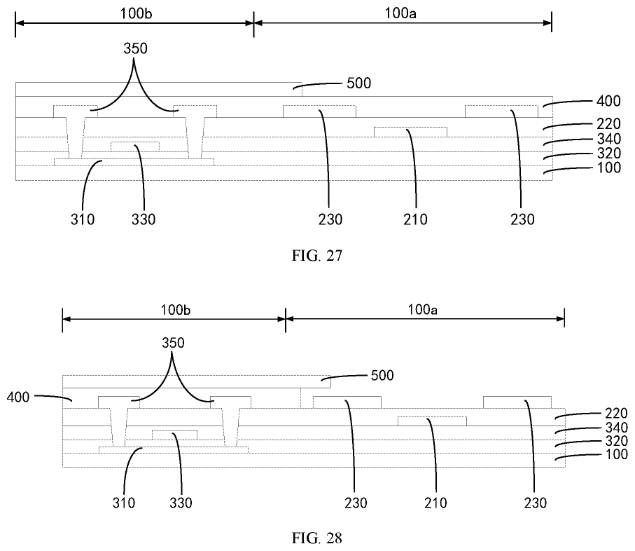

The film layer structure obtained through step S905 is shown in FIG. 27.

Optionally, in step S905, a photoresist may be coated on the sacrificial layer 400, and then the photoresist is patterned through exposure and development processes to obtain the photoresist structure 500.

Optionally, the photoresist completely covers the first region 100a and the second region 100b of the thin film transistor film layer, and is in contact with the side of the sacrificial layer 400 away from the substrate layer 100.

In S906, a part of the sacrificial layer is stripped off by taking the photoresist structure as a mask, to expose the part of the first source-drain structure, or to expose the part of the first source-drain structure and the part of the first buffer layer.

The film layer structure obtained through step S906 is shown in FIG. 27.

Optionally, in step S906, a part of the sacrificial layer 400 is stripped off by stripping the developing solution with the photoresist structure 500 as a mask. After stripping and development, at the edge of the sacrificial layer 400 is retracted laterally to some extent. This lateral retraction facilitates the fracture between the part of the oxide semiconductor layer 600 deposited on the first source-drain structure 230 and the part of the oxide semiconductor layer 600 deposited on the photoresist structure 500 subsequently.

In S907, an oxide semiconductor layer is deposited on the photoresist structure and the exposed part of the first source-drain structure. Alternatively, an oxide semiconductor layer is deposited on the photoresist structure, the exposed part of the first source-drain structure and the exposed part of the first buffer layer.

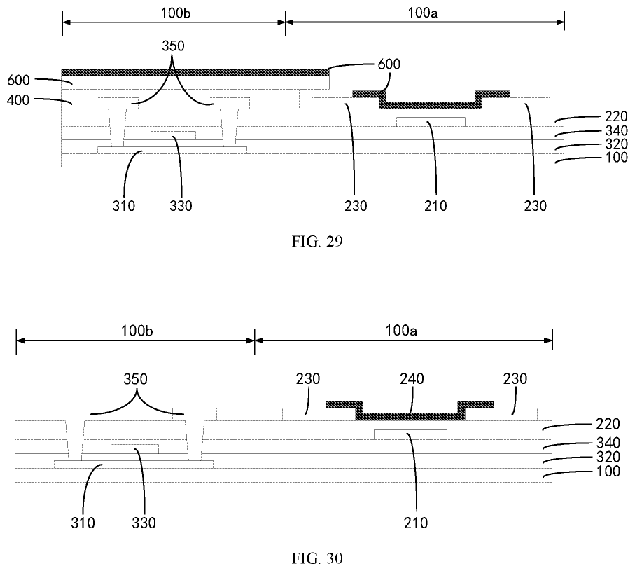

The film layer structure obtained through step S907 is shown in FIG. 29.

Since at the edge of the sacrificial layer 400 is retracted laterally by stripping and developing in step S906, in the oxide semiconductor layer 600 obtained in step S907, the part of the oxide semiconductor layer 600 disposed on the first source-drain structure 230 and the part of the oxide semiconductor layer 600 deposited on the photoresist structure 500 undergoes a fracture. This fracture causes a gap to be formed at the edge of the remaining sacrificial layer 400, which can facilitate the contact between the remaining sacrificial layer 400 and the lift-off developer solution in the subsequent process, so as to smoothly strip off the remaining sacrificial layer 400.

Optionally, the oxide semiconductor layer 600 may be made of an indium gallium zinc oxide (IGZO) material.

In S908, the remaining sacrificial layer is stripped off to obtain the oxide semiconductor structure that is in contact with the part of the first source-drain structure.

The film layer structure obtained through step S908 is shown in FIG. 30.

Through steps S904 to S908, the oxide semiconductor layer 600 is patterned by a stripping process to obtain the oxide semiconductor structure 240 configured to form a channel.

In S909, a first insulating layer is prepared on the side of the oxide semiconductor structure, the side of the first source-drain structure and the side of the third source-drain structure which are away from the first buffer layer, and a second gate structure is prepared on the side, away from the first gate structure, of the part of the first insulating layer which is disposed in the first region.

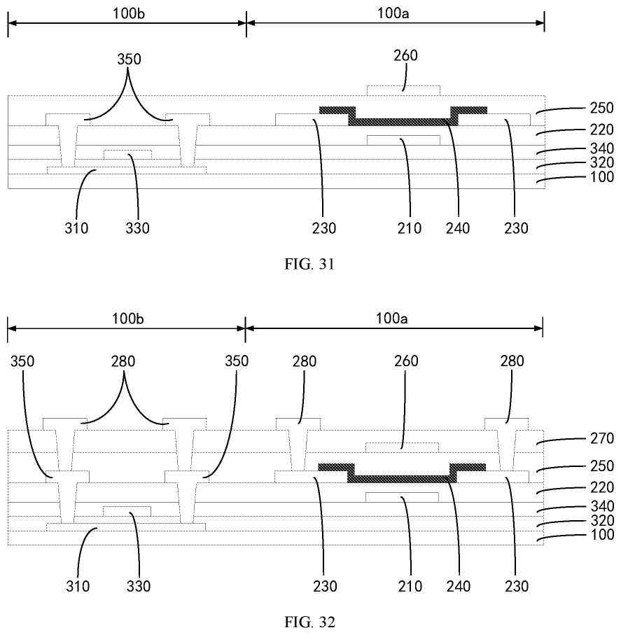

The film layer structure obtained through step S909 is shown in FIG. 31.

Optionally, the first insulating layer 250 covers the first region 100a and the second region 100b of the thin film transistor film layer, and is in contact with the side of the first buffer layer 220, the side of the third source-drain structure 350, the side of the first source-drain structure 230 and the side of the oxide semiconductor structure 240 which are away from the substrate layer 100.

Optionally, the first insulating layer 250 may be made of silicon monoxide.

Optionally, when the second gate structure 260 is prepared, a second gate layer may be deposited on the side of the first insulating layer 250 away from the substrate layer 100 first. The second gate layer is then patterned to obtain the second gate structure 260 of the LTPO device structure disposed in the first region 100a.

In S910, a second source-drain structure is prepared on the side of the first insulating layer away from the first buffer layer, and at least part of the second source-drain structure disposed in the first region is enabled to be electrically connected to the other part of the first source-drain structure, and at least part of the second source-drain structure disposed in the second region is enabled to be electrically connected to the third source-drain structure.

The film layer structure obtained through step S910 is shown in FIG. 32.

Optionally, in S910, a second insulating layer 270 may be deposited on the side of the first insulating layer 250 and the side of the second gate structure 260 which are away from the first insulating layer 250 first. Next, the second insulating layer 270 and the first insulating layer 250 are etched to obtain a first through hole and a second through hole. At least a partial region of the other part of the first source-drain structure 230 is exposed from the first through hole, and at least part of the third source-drain structure 350 is exposed from the second through hole. A second source-drain layer is then deposited on the second insulating layer 270 and in the first though hole and the second through hole. The second source-drain layer is then patterned to obtain a second source-drain structure 280. A part of the second source-drain structure 280 is electrically connected to the other part of the first source-drain structure 230, and the other part of the second source-drain structure 280 is electrically connected to the third source-drain structure 350.

Optionally, the second insulating layer 270 is in contact with both the side of the first insulating layer 250 and the side of the second gate structure 260 which are away from the substrate layer 100.

In S911, an anode structure is prepared on the side of the second insulating layer and the side of the second source-drain structure which are away from the substrate layer.

The film layer structure obtained through step S911 is shown in FIG. 6. That is, a thin film transistor film layer provided by the embodiments of the present disclosure is obtained.

Optionally, in step S911, a planarization layer 360 may be deposited on the second insulating layer 270 and the second source-drain structure 280 first. Next, the planarization layer 360 is etched to obtain a fourth through hole from which a part of the second source-drain structure 280 is exposed. The exposed part of the second source-drain structure 280 is electrically connected to the third source-drain structure 350. Then, an anode layer is deposited on the planarization layer 360 and in the fourth through hole. Afterwards, the anode layer is patterned to obtain an anode structure 370 that is electrically connected to a part of the second source-drain structure 280.

With the application of the embodiments of the present disclosure, at least the following beneficial effects can be achieved.

1. The switching device structure provided in the embodiments adopts a LTPO structure, which has the advantage of low electric leakage and can effectively reduce the power consumption. In the switching device structure, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

2. The projection of one end of the oxide semiconductor structure 240 on the substrate layer 100 overlaps with the projection of a part of the first source structure 231 on the substrate laver 100; and the projection of the other end of the oxide semiconductor structure 240 on the substrate layer 100 overlaps with the projection of a part of the first drain structure 232 on the substrate layer 100. Therefore, the contact area between the oxide semiconductor structure 240 and the first source structure 231 and the contact area between the oxide semiconductor structure 240 and the first drain structure 232 can be increased, thereby enhancing the effectiveness of electrical connection.

3. The thin film transistor film layer provided by the embodiments adopts a LTPO structure that integrates the LTPS device and the LTPO device. The current source can be supplied to the OLED for display by taking advantage of the characteristics of fast response speed and large turn-on current of the LTPS device. Meanwhile, the power consumption of the thin film transistor film layer can be reduced by taking advantage of the characteristic of low electric leakage of the LTPO device. In the LTPO device, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

4. The third source-drain structure 350 and the first source-drain structure 230 of the switching device structure may be disposed in the same layer, as long as the third source-drain structure 350 and the first source-drain structure 230 are insulated from each other, such as being spaced apart from each other, which can facilitate the thinning of the film layer of the device, and also facilitate the combination of the preparation process of the third source-drain structure 350 and the preparation of the first source-drain structure 230.

5. The third gate structure 330 and the first gate structure 210 are disposed in different layers and are spaced apart by the fourth insulating layer 340, which can further ensure the insulation between the third gate structure 330 and the first gate structure 210.

6. The thin film transistor film layer in the display panel provided in the embodiments adopts a LTPO structure that integrates the LTPS device and the LTPO device. The current source can be supplied to the OLED for display by taking advantage of the characteristics of fast response speed and large turn-on current of the LTPS device. Meanwhile, the power consumption of the thin film transistor film layer can be reduced by taking advantage of the characteristic of low electric leakage of the LTPO device. In the LTPO device, the first source-drain structure 230 is used as a bridge between the second source-drain structure 280 and the oxide semiconductor structure 240, such that the via hole electrically connected to the second source-drain structure 280 is not in direct contact with the oxide semiconductor structure 240, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption of the entire display panel.

7. According to the method for preparing a switching device structure provided in the embodiments of the present disclosure, the oxide semiconductor structure 240 is electrically connected to a part of the first source-drain structure 230, and the second source-drain structure 280 is electrically connected to the other part (i.e., a part that is not connected to the oxide semiconductor structure 240) of the first source-drain structure 230. That is, the first source-drain structure 230 is used as a bridge between the second source-drain structure 280 and the oxide semiconductor structure 240, such that an etching gas is not in contact with the surface layer of the oxide semiconductor structure 240 when the via hole electrically connected to the second source-drain structure 280 is prepared, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

8. Compared with the process of patterning the oxide semiconductor layer 600 by an etching process, the oxide semiconductor layer 600 is patterned by a stripping process in the embodiments of the present disclosure, which can avoid the possible influence on the first source-drain structure 230 caused by of compatibility, for example, the possible damage to the first source-drain structure 230 caused by the etching substance (such as an etching solution).

9. According to the method for preparing the thin film transistor film layer provided by the embodiments of the present disclosure, the LTPO device structure of the thin film transistor film layer is prepared in the first region of the thin film transistor film layer, and the polysilicon device structure is prepared in the second region of the thin film transistor film layer. That is, the thin film transistor film layer that integrates the polycrystalline silicon device structure and the LTPO device may be prepared. In this way, the current source can be supplied to the OLED for display by taking advantage of the characteristics of fast response speed and large turn-on current of the LTPS device. Meanwhile, the power consumption of the thin film transistor film layer is reduced by taking advantage of the characteristic of low electric leakage of the LTPO device.

10. The first gate structure 210, the first source-drain structure 230, the oxide semiconductor structure 240 and the second source-drain structure 280 constitute the main functional film layers of the LTPO device structure. In the process of preparing the LTPO device structure, the oxide semiconductor structure 240 may be electrically connected to a part of the first source-drain structure 230, and the second source-drain structure 280 is electrically connected to the other part (i.e., a part that is not connected to the oxide semiconductor structure 240) of the first source-drain structure 230. That is, the first source-drain structure 230 is used as a bridge between the second source-drain structure 280 and the oxide semiconductor structure 240, such that the etching gas is not in contact with the surface layer of the oxide semiconductor structure 240 when the via hole electrically connected to the second source-drain structure 280 is prepared, which can effectively prevent the damage to the surface of the oxide semiconductor structure 240 during the preparing process, or the defect state of the oxide semiconductor structure 240. Therefore, the stability of the oxide semiconductor structure 240 can be effectively improved and the electric leakage of the oxide semiconductor structure 240 can be reduced, thereby reducing the power consumption.

11. The first source-drain structure 230 of the LTPO device structure and the third source-drain structure 350 of the polysilicon device structure are prepared simultaneously on the side of the first buffer layer 220 away from the substrate layer 100. In an exemplary embodiment, the first source-drain structure 230 is prepared in the first region 100a, and the third source-drain structure 350 is prepared in the second region 100b, which facilitates the combination of the preparation process of the first source-drain structure 230 and the preparation process of the third source-drain structure 350 to shorten the preparing process, and also facilitates the arrangement of the first source-drain structure 230 and the third source-drain structure 350 in the same layer to make the thin film transistor film layer thinner.

12. The second source-drain structure 280 of the LTPO device structure and the third source-drain structure 350 of the polysilicon device structure are prepared simultaneously on the first insulating layer 250 and the side of the second gate structure 260 away from the first insulating layer 250, which facilitates the combination of the preparation process of the third source-drain structure 350 and the preparation process of the second source-drain structure 280 to shorten the manufacturing process, and meanwhile facilitates the arrangement of the third source-drain structure 350 and the first source-drain structure 230 in the same layer to make the thin film transistor film layer thinner, as long as the third source-drain structure 350 and the first source-drain structure 230 are insulated from each other, for example, spaced apart from each other in the patterning process.

It can be understood by those skilled in the art that the steps, measures and solutions in operations, methods and processes discussed in the present disclosure may be exchanged, modified, combined or deleted. Furthermore, other steps, measures and solutions that include those in the operations, methods and processes discussed in the present disclosure may also be exchanged, modified, rearranged, split, combined or deleted. Furthermore, the steps, measures and solutions in the prior art that include those in the operations, methods and processes discussed in the present disclosure may also be exchanged, modified, rearranged, split, combined or deleted.

In the descriptions of the present disclosure, it should be understood that the orientation or position relations indicated by terms of “central”, “upper”, “lower”, “front”, “rear”, “left”, “right”, “vertical” “horizontal”, “top”, “bottom”, “in”, “out”, and the like are based on orientation or the position relations shown in the drawings, and are only intended for the convenient and simplified descriptions of the present disclosure, instead of indicating or implying that the indicated devices or elements must be in the particular orientations or be constructed and operated in the particular orientations, and thus cannot be construed as limitations of the present disclosure.

The terms “first” and “second” are only for the purpose of descriptions and should not be construed as indicating or implying relative importance or implicitly indicating the number of technical features indicated. Thus, the features defined by the terms “first” and “second” may include one or more of the features either explicitly or implicitly. In the descriptions of the present disclosure, the term “a plurality of” refers to two or more, unless otherwise specified.

In the descriptions of the present disclosure, it should be noted that, unless otherwise definitely specified and limited, the terms “mounted”, “connected with”, and “connected to” are to be understood broadly. For example, the connection may be fixed connection, or detachable connection or integrated connection; and may be direct connection, or indirect connection via an intermediation, or communication of two elements. Persons of ordinary skill in the art can understand the meaning of the above terms in the present disclosure in accordance with specific conditions.

In the descriptions of the specification, the features, structures, materials or characteristics can be integrated with any one or more embodiments or examples in a proper manner.

It should be understood that although the various steps in the flowchart of the drawings are sequentially displayed as indicated by the arrows, these steps are not necessarily executed in the sequence indicated by the arrows. Unless explicitly stated herein, the sequence of executing these steps is not strictly limited, and may be performed in other sequences. Moreover, at least some of the steps in the flowchart of the drawings may include a plurality of sub-steps or stages. The sub-steps or stages are not necessarily completed at the same time, but may be executed at different moments. The sub-steps or stages is also not necessarily executed sequentially, but may be executed in turn or alternately with at least some of other steps, stages of other steps, or stages.

The above descriptions are only some embodiments of the present disclosure. It should be noted that those skilled in the art may also make improvements and modifications without departing from the principles of the present disclosure and the improvements and modifications should be included in the scope of protection of the present disclosure.

What is claimed is:

1. A switching device structure, comprising:
a first gate structure, disposed on a side of a substrate layer;
a first buffer layer, disposed on a side of the first gate structure and the side of the substrate layer, the first gate structure being disposed between the substrate layer and the first buffer layer;
a first source-drain structure, disposed on a side of the first buffer layer away from the substrate layer;
an oxide semiconductor structure, disposed on the side of the first buffer layer away from the substrate layer, the oxide semiconductor structure being in contact with a part of the first source-drain structure;
a first insulating layer, disposed on a side of the first source-drain structure and a side of the oxide semiconductor structure which are away from the first buffer layer;
a second gate structure, disposed on a side of the first insulating layer away from the first buffer layer; and
a second source-drain structure, disposed on the side of the first insulating layer away from the first buffer layer, the second source-drain structure being electrically connected to an other part of the first source-drain structure.

2. The switching device structure according to claim 1, wherein the first source-drain structure comprises a first source structure and a first drain structure that are separated from each other, wherein one end of the oxide semiconductor structure is connected to a part of the first source structure, and the other end of the oxide semiconductor structure is connected to a part of the first drain structure; and
the second source-drain structure comprises a second source structure and a second drain structure that are separated from each other, wherein the second source structure is electrically connected to an other part of the first source structure, and the second drain structure is electrically connected to an other part of the first drain structure.

3. The switching device structure according to claim 2, wherein the first source structure, the first drain structure and at least part of the oxide semiconductor structure are in contact with the first buffer layer.

4. The switching device structure according to claim 2, wherein a projection of the one end of the oxide semiconductor structure on the substrate layer overlaps with a projection of the part of the first source structure on the substrate layer, and a projection of the other end of the oxide semiconductor structure on the substrate layer overlaps with a projection of the part of the first drain structure on the substrate layer.

5. The switching device structure according to claim 4, wherein a positional relationship between the oxide semiconductor structure and the first source-drain structure satisfies at least one of the following:
the one end of the oxide semiconductor structure is disposed on a side, away from the first buffer layer, of the part of the first source structure; and
the other end of the oxide semiconductor structure is disposed on a side, away from the first buffer layer, of the part of the first drain structure.

6. A thin film transistor film layer, comprising a polysilicon device structure and the switching device structure according to claim 1, wherein
the polysilicon device structure comprises a polysilicon structure, a third insulating layer, a third gate structure, a fourth insulating layer, and a third source-drain structure that are sequentially laminated on a side of a substrate layer;
a first gate structure, a first source-drain structure, an oxide semiconductor structure, and some of second source-drain structures in the switching device structure are disposed in a first region of the thin film transistor film layer;
the polysilicon structure, the third gate structure, the third source-drain structure, and others of the second source-drain structures are disposed in a second region of the thin film transistor film layer;
the third source-drain structure is electrically connected to the polysilicon structure; and
each of the others of the second source-drain structures is electrically connected to a third source-drain structure.

7. The thin film transistor film layer according to claim 6, wherein the third source-drain structure and the first source-drain structure of the switching device structure are both disposed on a side of a first buffer layer away from the substrate layer, and are in contact with the first buffer layer.

8. The thin film transistor film layer according to claim 6, wherein the third gate structure is disposed on a side of the third insulating layer away from the substrate layer;
the fourth insulating layer is disposed on a side of the third gate structure and the side of the third insulating layer which are away from the substrate layer;
the first gate structure is disposed on a side of the fourth insulating layer away from the third insulating layer; and
the first buffer layer is disposed on a side of the first gate structure and the side of the fourth insulating layer which are away from the third insulating layer.

9. The thin film transistor film layer according to claim 6, wherein at least some of the others of the second source-drain structures are configured to be electrically connected to an anode layer.

10. A display panel, comprising the thin film transistor film layer as defined in claim 6, an anode layer, a light-emitting layer and a cathode layer which are sequentially laminated, wherein at least some of the others of second source-drain structures of the thin film transistor film layer are configured to be electrically connected to the anode layer.

11. A display apparatus, comprising the display panel as defined in claim 10.

12. A method for preparing a switching device structure, comprising:
preparing a first gate structure, a first buffer layer and a first source-drain structure which are sequentially laminated on a side of a substrate layer;
preparing an oxide semiconductor structure on the first buffer layer, wherein the oxide semiconductor structure is in contact with a part of the first source-drain structure;
depositing a first insulating layer on the first buffer layer, the first source-drain structure and the oxide semiconductor structure; and
preparing a second gate structure and a second source-drain structure on the first insulating layer, wherein the second source-drain structure is electrically connected to an other part of the first source-drain structure.

13. The method according to claim 12, wherein preparing the oxide semiconductor structure on the first buffer layer comprises:
coating a sacrificial layer on the first buffer layer and the first source-drain structure;
preparing a photoresist structure on the sacrificial layer, wherein a projection of a hollowed-out portion of the photoresist structure on the substrate layer at least partially overlaps with a projection of the part of the first source-drain structure on the substrate layer, and a projection of a part of the first buffer layer on the substrate layer;
stripping off a part of the sacrificial layer by taking the photoresist structure as a mask, to expose the part of the first source-drain structure;
depositing an oxide semiconductor layer on the photoresist structure and the exposed part of the first source-drain structure; and
stripping off the remaining sacrificial layer to obtain the oxide semiconductor structure that is in contact with the part of the first source-drain structure.

14. The method according to claim 12, wherein preparing the second gate structure and the second source-drain structure on the first insulating layer comprises:
preparing the second gate structure on the first insulating layer;
depositing a second insulating layer on the first insulating layer and the second gate structure;
etching the second insulating layer and the first insulating layer to obtain a first through hole, wherein at least a partial region of the other part of the first source-drain structure is exposed from the first through hole;
depositing a second source-drain layer on the second insulating layer and in the first through hole; and
patterning the second source-drain layer to obtain the second source-drain structure that is electrically connected to the other part of the first source-drain structure.

15. A method for preparing a thin film transistor film layer, comprising:
preparing a substrate layer, wherein the thin film transistor film layer comprises a first region and a second region; and a polysilicon device structure in the thin film transistor film layer is disposed in the second region;
preparing a first gate structure on a side, away from the substrate layer, of a first portion of the substrate layer which is disposed in the first region;
preparing a first buffer layer on the substrate layer and on a side of the first gate structure away from the substrate layer;
preparing a first source-drain structure on a side, away from the substrate layer, of a part of the first buffer layer which is disposed in the first region;
preparing an oxide semiconductor structure on a side, away from the first gate structure, of the part of the first buffer layer which is disposed in the first region, and enabling the oxide semiconductor structure to be connected to a part of the first source-drain structure;
preparing a first insulating layer on a side of the oxide semiconductor structure and a side of the first source-drain structure which are away from the first buffer layer;
preparing a second gate structure on a side, away from the first gate structure, of a part of the first insulating layer which is disposed in the first region; and
preparing a second source-drain structure on a side of the first insulating layer away from the first buffer layer, and enabling a part of the second source-drain structure to be electrically connected to an other part of the first source-drain structure.

16. The method according to claim 15, wherein when preparing first source-drain structure on the side, away from the substrate layer, of the part of the first buffer layer which is disposed in the first region, the method further comprises:
preparing a third source-drain structure of the polysilicon device structure on a side, away from the substrate layer, of a part of the first buffer layer which is disposed in the second region, and enabling the third source-drain structure to be electrically connected to the polysilicon structure.

17. The method according to claim 16, wherein preparing the oxide semiconductor structure on the side, away from the first gate structure, of the part of the first buffer layer which is disposed in the first region comprises:
coating a sacrificial layer on the first buffer layer, the third source-drain structure and the first source-drain structure;
preparing a photoresist structure on the sacrificial layer, wherein a projection of a hollowed-out portion of the photoresist structure on the substrate layer at least partially overlaps with a projection of the part of the first source-drain structure on the substrate layer, and a projection of a part of the first buffer layer on the substrate layer;
stripping off a part of the sacrificial layer by taking the photoresist structure as a mask, to expose the part of the first source-drain structure;
depositing an oxide semiconductor layer on the photoresist structure and the exposed part of the first source-drain structure; and
stripping off the remaining sacrificial layer to obtain the oxide semiconductor structure that is in contact with the part of the first source-drain structure.

18. The method according to claim 17, wherein preparing the first insulating layer on the side of the oxide semiconductor structure and the side of the first source-drain structure which are away from the first buffer layer comprises:
preparing the first insulating layer on the side of the oxide semiconductor structure, the side of the first source-drain structure and the side of the third source-drain structure which are away from the first buffer layer.

19. The method according to claim 18, wherein preparing the second source-drain structure on the side of the first insulating layer away from the first buffer layer comprises:
preparing a second insulating layer on the first insulating layer and a side of the second gate structure away from the first insulating layer;
etching the second insulating layer and the first insulating layer to obtain a first through hole and a second through hole, wherein at least a partial region of the other part of the first source-drain structure is exposed from the first through hole, and at least part of the third source-drain structure is exposed from the second through hole;
depositing a second source-drain layer on the second insulating layer, and in the first through hole and the second through hole; and
patterning the second source-drain layer to obtain the second source-drain structure, wherein a part of the second source-drain structure is electrically connected to the other part of the first source-drain structure, and an other part of the second source-drain structure is electrically connected to the third source-drain structure.

20. The method according to claim 15, wherein preparing the substrate layer comprises:
preparing a polysilicon structure of the polysilicon device structure on a side of a part of the second buffer layer which is disposed in the second region;
preparing a third insulating layer on a side of the polysilicon structure and a side of the second buffer layer;
preparing a third gate structure of the polysilicon device structure on a side, away from the polysilicon structure, of a part of the third insulating layer which is disposed in the second region; and
preparing a fourth insulating layer on a side of the third gate structure and a side of the third insulating layer which are away from the second buffer layer.
